(19) United States
(12) Patent Application Publication
(10) Pub. No.: US 2024/0395506 A1
(43) Pub. Date: Nov. 28, 2024

(54) CONICAL IMPEDANCE TRANSFORMER FOR MICROWAVE PLASMA PROCESSING

(71) Applicant: Applied Materials, Inc., Santa Clara, CA (US)

(72) Inventors: Kenneth Brian Doering, San Jose, CA (US); Xiaokang Yang, Fremont, CA (US); Sathya Swaroop Ganta, Sunnyvale, CA (US)

(73) Assignee: Applied Materials, Inc., Santa Clara, CA (US)

(21) Appl. No.: 18/388,250

(22) Filed: Nov. 9, 2023

Related U.S. Application Data
(60) Provisional application No. 63/469,132, filed on May 26, 2023.

(51) Int. Cl. H01J 37/32

(52) U.S. Cl. CPC H01J 37/3222

(57) ABSTRACT

A microwave plasma impedance transformers comprising a thermal break and methods of use are described. The impedance transformer comprises a housing having a first end and a second end defining a length of the housing. The housing has a channel with channel walls extending through the length from the first end to the second end, and the channel has an opening in the first end of the housing with a first end diameter and an opening in the second end of the housing with a second end diameter. The first end diameter being greater than the second end diameter. The channel acts as a conical impedance transformer.

### CROSS-REFERENCE TO RELATED APPLICATIONS

This application claims priority to U.S. Provisional Application No. 63/469,132, filed May 26, 2023, the entire disclosure of which is hereby incorporated by reference herein.

### TECHNICAL FIELD

Embodiments of the disclosure generally relate to microwave plasma processing chambers for semiconductor manufacturing. In particular, embodiments of the disclosure relate conical impedance transformers (CIT) as a microwave fixed match/antennae in plasma processing.

### BACKGROUND

During semiconductor device manufacturing, numerous materials are formed on and removed from a substrate to form the underlying devices. Great efforts are generally expended to produce highly uniform material layers and device features. However, distributions in material layer thickness, critical dimension (CD), and the like nonetheless exist across a substrate. As semiconductor device dimensions shrink, such variations in thickness uniformity, CD uniformity, etc., become more difficult to tolerate.

Many deposition and etching processes in semiconductor manufacturing use a microwave plasma source to generate a plasma within a processing region of a processing chamber. A microwave plasma source often has multiple microwave antennae to transmit microwave power to the processing chamber. Each antenna in a conventional microwave plasma source has a thermal break and resonator for plasma generation. The thermal break has many weak points such as solder joints and exposed copper strips on a printed circuit board. A disconnect formed in the weak points can result in a failed antennae affecting the overall plasma uniformity within the processing chamber.

Additionally, the thermal break output impedance, thus resonance frequency can shift due to misalignment of the microwave antennae pin with the copper traces centered during manufacturing. This can result in high reflected power as well as large temperature variations/gradient on the copper traces; in worst case, it can damage (burn) the copper traces.

Thermal break failure happens frequently on process tools, and it can take a substantially long amount of time to troubleshoot, replace, and retune the resonant frequency of the antennae. Therefore, there is a need in the art for apparatus and methods to improve microwave antennae reliability in semiconductor manufacturing.

### SUMMARY

One or more embodiments of the disclosure are directed to impedance transformers including a thermal break. The thermal break includes a housing with a first end and a second end that define a length of the housing. The housing has a channel with channel walls extending through the length from the first end to the second end. The channel has an opening in the first end of the housing with a first end diameter and an opening in the second end of the housing with a second end diameter. The first end diameter is greater than the second end diameter. The channel acts as a conical impedance transformer.

A plasma source comprising a cooled plate, a pumping ring, a thermal break and a plasma plate. The cooled plate comprises a plurality of openings therethrough. The pumping ring is below the cooled plate. The thermal break is positioned within at least some of the plurality of openings. The thermal break includes a housing with a first end and a second end that define a length of the housing. The housing has a channel with channel walls extending through the length from the first end to the second end. The channel has an opening in the first end of the housing with a first end diameter and an opening in the second end of the housing with a second end diameter. The first end diameter is greater than the second end diameter. The channel acts as a conical impedance transformer. The second end of the thermal break extends below a bottom surface of the cooled plate and is connected to the pumping ring. The plasma plate is below the pumping ring, the plasma plate comprises a plurality of pin openings in a top surface thereof. Each of the thermal breaks comprises a microwave antennae pin positioned within the channel in the housing. The microwave antennae pins extend a distance from the second end of the housing of the thermal breaks into the pin openings in the plasma plate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. Additionally, it should be noted that the shading applied to the Figures is intended to aid in differentiation of the components and is not related to the materials of constructions.

FIG. 1 shows a graph of reflected power as a function of frequency for a conical impedance transformer according to one or more embodiment of the disclosure;

FIG. 2 shows an orthographic view of the thermal break portion of an impedance transformer according to one or more embodiment of the disclosure;

FIG. 3 shows a cross-sectional view of the thermal break portion of the impedance transformer of FIG. 2 taken along line 3-3′;

FIG. 4A shows a schematic representation of a portion of the housing of the thermal break in which the channel walls have a straight or linear profile according to one or more embodiment of the disclosure;

FIG. 4B shows a schematic representation of a portion of the housing of the thermal break in which the channel walls have a curved taper profile according to one or more embodiment of the disclosure;

FIG. 4C shows a schematic representation of a portion of the housing of the thermal break in which the channel walls have a curved taper profile with two linear facets according to one or more embodiment of the disclosure;

FIG. 4D shows a schematic representation of a portion of the housing of the thermal break in which the channel walls have a curved taper profile with four linear facets according to one or more embodiment of the disclosure;

FIG. 5 shows a portion of a plasma source incorporating an impedance transformer with thermal break according to one or more embodiment of the disclosure;

FIG. 6 shows an expanded view of region VI of the embodiment shown in FIG. 5;

FIG. 7 shows an expanded view of region VII of the embodiment shown in FIG. 5;

FIG. 8 shows a bottom orthographic view of a thermal break with screw threads at the second end of the housing according to one or more embodiment of the disclosure;

FIG. 9, shows a partial cross-sectional schematic view of a plasma source incorporating impedance transformers with thermal breaks according to one or more embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Embodiments of the disclosure provide apparatus and methods to increase the microwave plasma uniformity. Some embodiments provide conical impedance transformers with a simpler, more robust design, than previous resonators or thermal breaks used for microwave plasma sources. In some embodiments, the conical impedance transformer advantageously has no solder joints. In some embodiments, the conical impedance transformer advantageously has no copper strips. In some embodiments, the conical impedance transformer advantageously has a wider operating frequency bandwidth than current designs. In some embodiments, the conical impedance transformer is easy to replace and/or build. In some embodiments, the conical impedance transformer advantageously is less expensive than current resonator or thermal break designs.

In some embodiments, the conical impedance transformer has a tightly controlled tapered or conical shaped housing to control impedance. The tapered or conical shaped housing reduces reflected power and increases the operating window for the microwave source.

In some embodiments, the conical impedance transformer includes a microwave antenna. In some embodiments, the conical impedance transformer has a beryllium copper (BeCu) rod that acts as a microwave antenna. In some embodiments, the antenna end inserts in a dielectric (e.g., alumina (aluminum oxide)) faceplate/showerhead in the microwave plasma source.

In some embodiments, the other end of the conical impedance transformer has an n-type connector for a coaxial cable connection. The cable provides microwave energy from a power amplifier. The antenna radiates the energy through the alumina faceplate and forms a plasma below the faceplate and above the heater wafer that forms the controller process zone of the processing chamber.

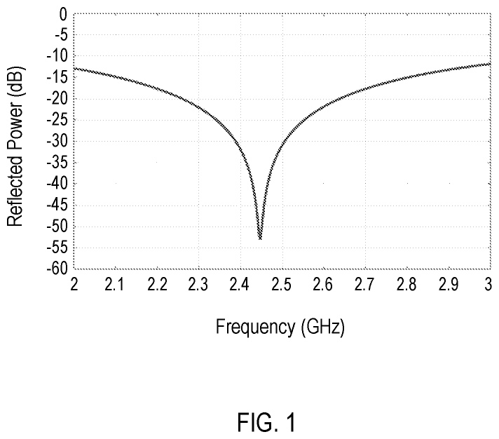

In some embodiments, the thermal break is a standard ¼ wavelength impedance transformer and has a narrow frequency bandwidth; achieving a good impedance matching condition at a fixed frequency and at a fixed antenna load impedance. In some embodiments, a conical impedance transformer is a broadband impedance matching approach which utilizes a continuously curved taper (Klopfenstein taper) on the inner surface of the outer conductor of the transmission line, as a result, the conical impedance transformer can smoothly vary the characteristic impedance along the curved surface to obtain an extremely low reflection coefficient (−30 dB) of microwave power over a full bandwidth (from 2.40 GHz to 2.50 GHz) of solid state power amplifier, as shown in FIG. 1. At center frequency of 2.45 GHz, for example, the reflected power of conical impedance transformer is 0 (−52 dB), which means the conical impedance transformer can achieve a perfect impedance matching within a wider frequency bandwidth. In some embodiments, the conical impedance transformer is configured so that the length of the taper segment can be as short as ½ wavelength.

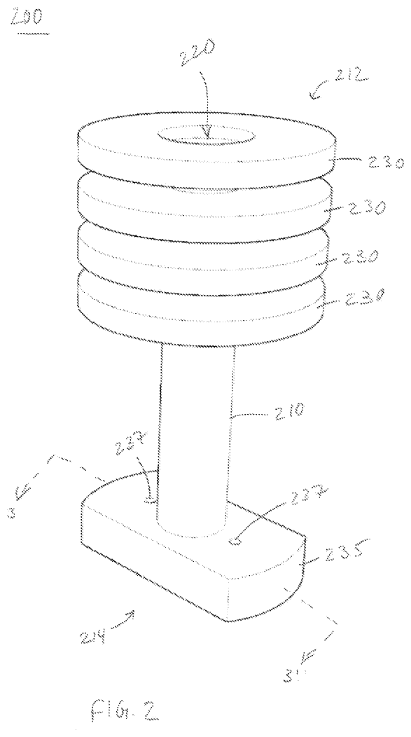

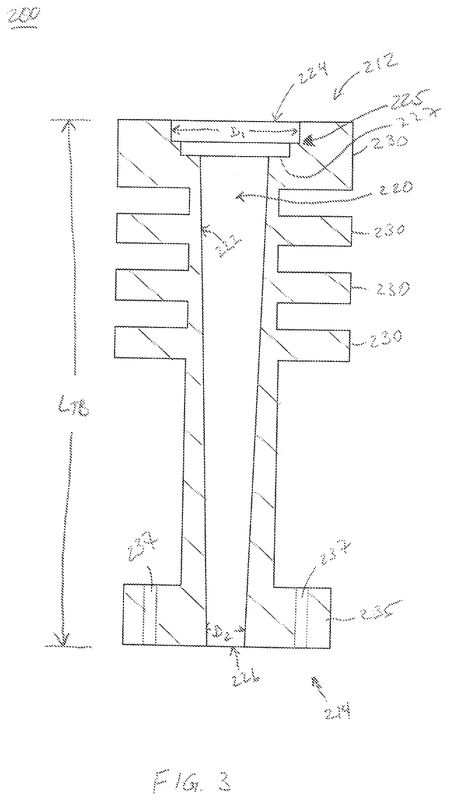

FIG. 2 shows a thermal break 200 portion of an impedance transformer 100 according to one or more embodiment of the disclosure. FIG. 3 shows a cross-sectional view of the thermal break 200 of the impedance transformer 100 of FIG. 2 taken along line 3-3′. The thermal break 200 comprises a housing 210 having a first end 212 and a second end 214. The length L_{TB} of the thermal break 200 is defined from the first end 212 to the second end 214.

The housing 210 has a channel 220 with channel walls 222 extends through the length L_{TB} of the thermal break 200 from the first end 212 to the second end 214. The channel 220 has an opening 224 in the first end 212 of the housing 210 with a first end diameter D₁ and an opening 226 in the second end 214 of the housing 210 with a second end diameter D₂. The first end diameter D₁ is greater than the second end diameter D₂. The channel 220 acts as a conical impedance transformer for microwave power.

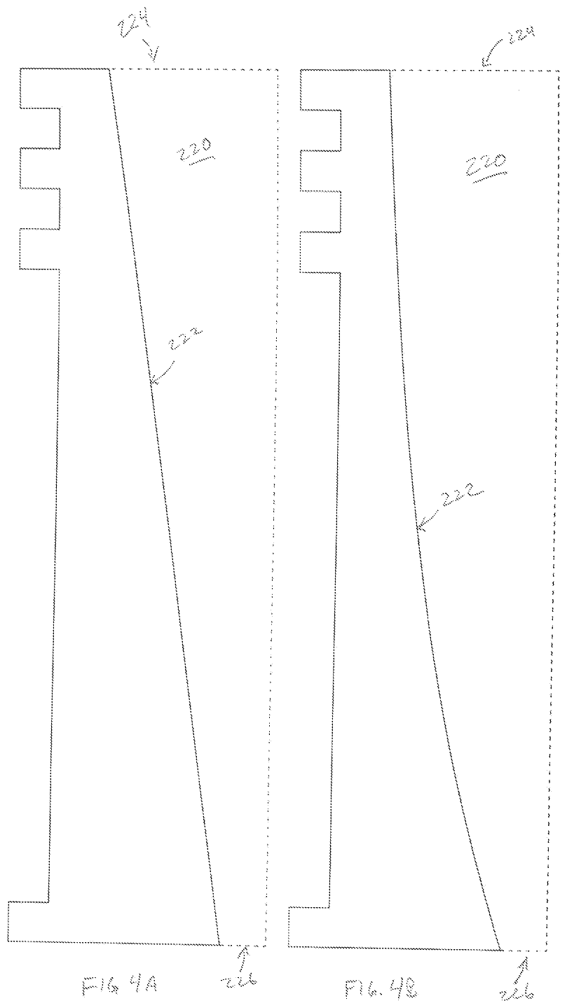

FIGS. 4A through 4D show different channel 220 profiles. The inventors have found that the channel wall 222 profile affects the ability of the thermal break 200 to act as a conical impedance transformer. FIG. 4A shows an embodiment of the housing 210 of the thermal break 200 in which the channel walls 222 have a straight or linear profile. FIG. 4B shows an embodiment of the housing 210 of the thermal break 200 in which the channel walls 222 have a curved taper profile. In the illustrated embodiment, the curved taper profile is a concave profile. However, the skilled artisan will recognize that the curved taper profile can be convex as well. The curved taper profile of some embodiments comprises a smooth transition along the length of the channel 220.

In some embodiments, as shown in FIGS. 4C and 4D, the curved taper profile of the channel 220 comprises a plurality of linear facets 228. FIG. 4C shows a curved taper profile with two linear facets; a first facet 228a and a second facet 228b. The inflection point 229a between the first facet 228a and the second facet 228b can be located at any suitable distance from the opening 224 in the first end 212 of the housing 210 along the length L_{TB} of the thermal break 200. In some embodiments, the inflection point 229a between the first facet 228a and second facet 228b occurs in the range of 40% to 60% of the length L_{TB} of the thermal break 200 measured from the first end 212 of the housing 210.

In some embodiments, there are more than two facets 228. In the embodiment illustrated in FIG. 4D, there are four linear facets 228; a first facet 228a, a second facet 228b, a third facet 228c and a fourth facet 228d. An inflection point 229a occurs between the first facet 228a and the second facet 228b, an inflection point 229b occurs between the second facet 228b and the third facet 228c, and an inflection point 229c occurs between the third facet 228c and the fourth facet 228d. The inflection points can occur at an suitable position along the length L_{TB} of the thermal break 200. In some embodiments, the inflection points are evenly spaced along the length of the thermal break so that the distance from the end of the facet near the first end of the housing 210 and the end of the facet near the second end of the housing 210 are the same. In some embodiments, the individual inflection points are spaced so that the length of the individual facets 228 are substantially the same. As used in this manner, the term “substantially the same” means that the length of any segment varies by no more than 10%, 5% or 2% from the average length of the facets.

The illustrated embodiments show two or four facets for the channel 220. However, the skilled artisan will recognize that there can be three, five or more facets. In some embodiments, there are greater than or equal to 2, 3, 4, 5, 6, 7, 8, 9 or 10 facets. In some embodiments, there are in the range of 2 to 15 facets.

The thermal break 200 can be made of any suitable material that can both transmit microwave energy and thermal energy. The thermal break 200 of some embodiments acts as both a conical impedance transformer and a heat sink to help prevent heat transfer from a component at one end of the thermal break 200 to the other end of the thermal break 200. In some embodiments, the housing 210 comprises aluminum or some other suitably conductive material.

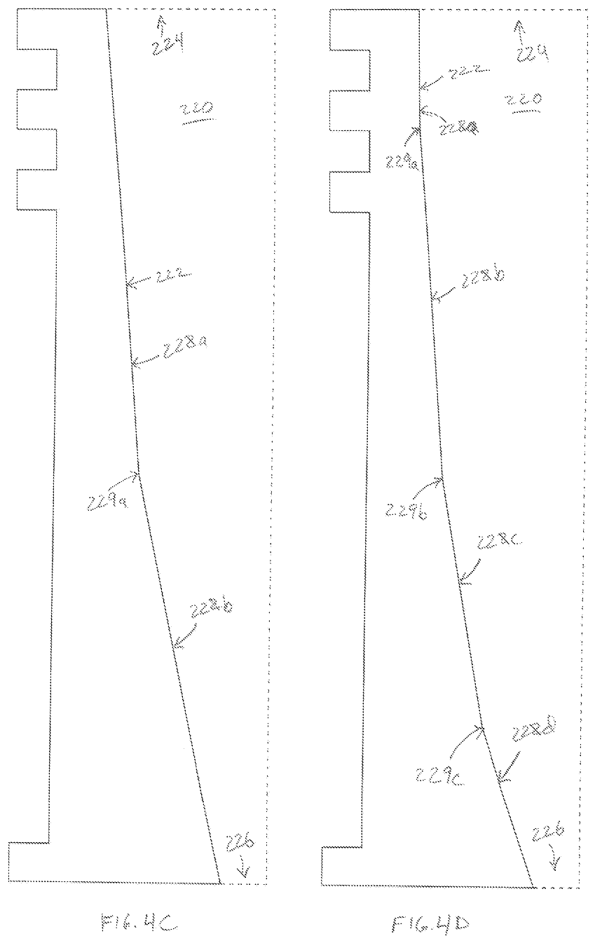

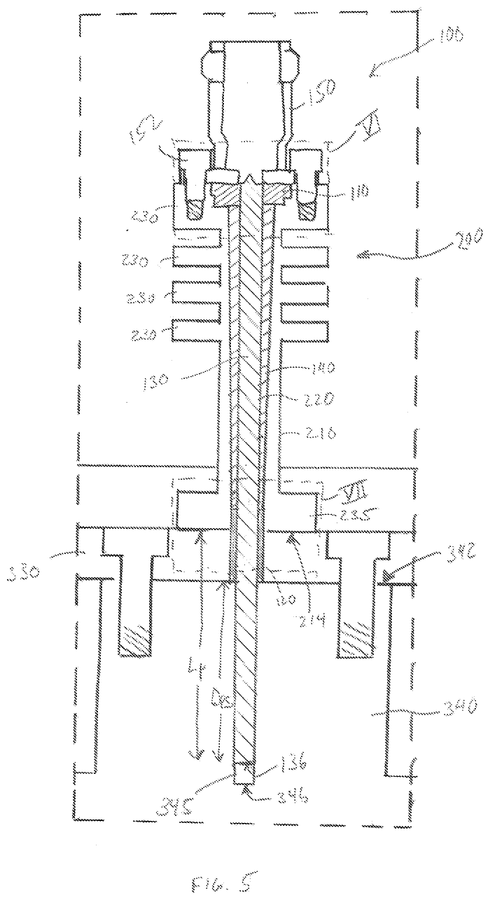

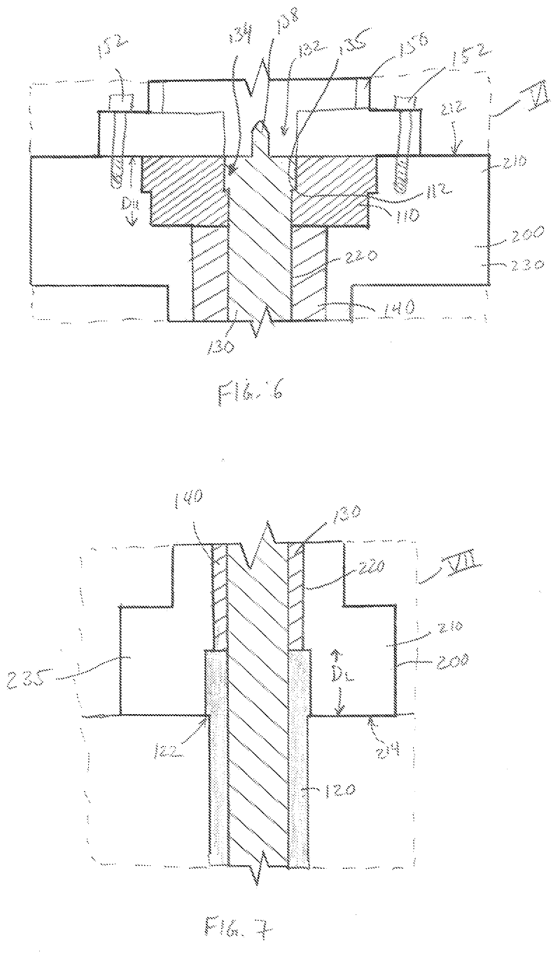

FIG. 5 shows an impedance transformer 100 according to one or more embodiment of the disclosure. FIG. 6 shows an expanded view of region VI of the embodiment shown in FIG. 5. FIG. 7 shows an expanded view of region VII of the embodiment shown in FIG. 5.

Referring to FIGS. 5 and 6, the impedance transformer 100 of some embodiments includes an upper sleeve 110 positioned within the housing 210 of the thermal break 200. The upper sleeve 110 extends a distance D_{U} into the housing 210 from the first end 212. The distance D_{U} of some embodiments is less than or equal to 25%, 20%, 15%, 10% or 5% of the length L_{TB} of the thermal break 200.

The channel 220 of some embodiments includes a stepped portion 225, as shown in FIG. 3. The stepped portion 225 creates a ledge 227, or in the illustrated embodiment, more than one ledge 227, upon which the upper sleeve 110 can be positioned. The ledge 227 creates a region to support a component positioned within the channel 220 without a mechanical connection. For example, the upper sleeve 110 can be shaped to rest on the ledge 227 of the stepped portion 225 of the channel 220 by gravity or a friction fit.

The upper sleeve 110 can be made of any suitable material that can electrically isolate a microwave antenna pin from the housing 210 of the thermal break 200. In some embodiments, the upper sleeve 110 comprises polytetrafluoroethylene (PTFE). In some embodiments, the thickness of the upper sleeve 110 depends on the dielectric properties of the material.

Referring to FIGS. 5 and 7, the impedance transformer 100 of some embodiments further comprises a lower sleeve 120 positioned within the housing 210 of the thermal break 200. The lower sleeve 120 extends a distance D_{L} into the housing 210 of the thermal break 200 from the second end 214. The distance D_{L} of some embodiments is less than or equal to 25%, 20%, 15%, 10% or 5% of the length L_{TB} of the thermal break 200. In some embodiments, the lower sleeve 120 extends out of the housing 210 of the thermal break 200.

In some embodiments, the lower sleeve 120 includes a stepped portion with a ledge 122 sized to rest on a complementary protrusion within the housing 210. The ledge 122 can be used to hold the lower sleeve 120 in position within the channel 220 of the thermal break 200 without using a mechanical fastener. In some embodiments, the lower sleeve 120 is held within the channel 220 by gravity or a friction fit.

The lower sleeve 120 can be made of any suitable material that can electrically isolate a microwave antenna pin from the housing 210 of the thermal break 200. In some embodiments, the lower sleeve 120 comprises polytetrafluoroethylene (PTFE). In some embodiments, the thickness of the lower sleeve 120 depends on the dielectric properties of the material used.

In some embodiments, the impedance transformer 100 further comprises a microwave antennae pin 130 positioned within the channel 220. The microwave antennae pin 130 can be any suitable length and diameter. The microwave antennae pin 130 extends a distance LP from the second end 214 of the housing 210.

In some embodiments, as shown in FIG. 6, the first end 132 of the microwave antennae pin 130 includes a stepped region 134 in which the diameter of the microwave antennae pin 130 increases to create a ledge 135. The ledge 135 can be used to hold the microwave antennae pin 130 in place on a complementary ledge 112 on the upper sleeve 110 of the impedance transformer 100.

In some embodiments, the diameter of the microwave antennae pin 130, not included the stepped region 134 is substantially uniform along the length of the microwave antennae pin 130. As used in this manner, the term “substantially uniform” means that the diameter does not vary by more than 0.05 mm along the length of the microwave antennae pin 130 below the stepped region 134. In some embodiments, the microwave antennae pin 130 has a diameter in the range of 3 mm to 4 mm.

In some embodiments, the diameter of the microwave antennae pin 130 decreases along the length of the microwave antennae pin 130 below the stepped region 134 so that the diameter of the microwave antennae pin 130 at the second end 136 is less than the diameter at the first end 132, measured adjacent the stepped region 134 toward the second end 136.

The microwave antennae pin 130 can be made of any suitable material known to the skilled artisan. In some embodiments, the microwave antennae pin 130 comprises a beryllium copper (BeCu) pin. In some embodiments, the microwave antennae pin 130 comprises any suitable highly conductive (electrically) material.

The portion of the length of the channel 220 between the upper sleeve 110 and lower sleeve 120 can comprise any suitable dielectric material 140 that can electrically isolate the microwave antenna pin 130 from the housing 210 of the thermal break 200. In some embodiments, the dielectric material 140 comprises and air gap or polytetrafluoroethylene (PTFE).

Referring back to FIGS. 2 and 3, in some embodiments, at least a portion of the length L_{TB} of the housing 210 comprises outwardly projecting and spaced apart vanes 230 for heat dissipation. The outwardly projecting and spaced apart vanes 230 increase the surface area of the housing 210 to improve heat dissipation. The embodiment illustrated in the claims shows four outwardly projecting and spaced apart vanes 230, including the first end 212 of the housing 210. The skilled artisan will recognize that this is merely one possible configuration and that more or less than four vanes can be included.

In some embodiments, the thermal break 200 includes a flange 235 at the second end 214 of the housing 210. The flange 235 illustrated includes two openings 237 that are configured to allow a fastener to be used to connect the second end 214 of the housing 210 to an adjacent component, for example, a pumping ring or ceramic plate.

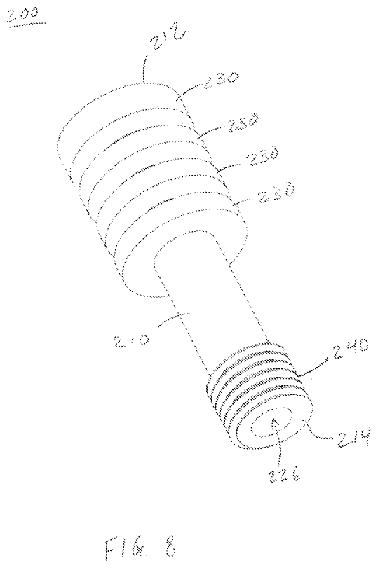

In some embodiments, as shown in FIG. 8, the thermal break 200 has screw threads 240 at the second end 214 of the housing 210. The screw threads 240 can be used in place of the flange 235 illustrated in FIGS. 2 and 3. The screw threads 240 can be any suitable size threads with any suitable length from the second end 214 of the housing 210, or can begin spaced a distance from the second end 214 extending along the length of the housing 210.

Referring again to FIGS. 5 and 6, in some embodiments, the impedance transformer 100 further comprises a coaxial connector 150 attached to the first end 212 of the housing 210 of the thermal break 200. In some embodiments, the coaxial connector 150 is secured to the housing 210 using one or more mechanical fasteners 152. Suitable mechanical fasteners 152 include, but are not limited to, bolts. In some embodiments, the first end 132 of the microwave antennae pin 130 includes an upper protrusion 138 that improves electrical connection with the coaxial connector 150. In some embodiments, the coaxial connector 150 is connected to the attached to the microwave antennae pin 130 by complementary screw threads. In some embodiments, the coaxial connector 150 is attached to the first end 212 of the housing 210 of the thermal break 200 using complementary screw threads. In some embodiments, threaded connections between the coaxial connector 150 to the first end 212 of the housing 210 and/or to the first end 132 of the microwave antennae pin 130 provides a more robust electrical connection.

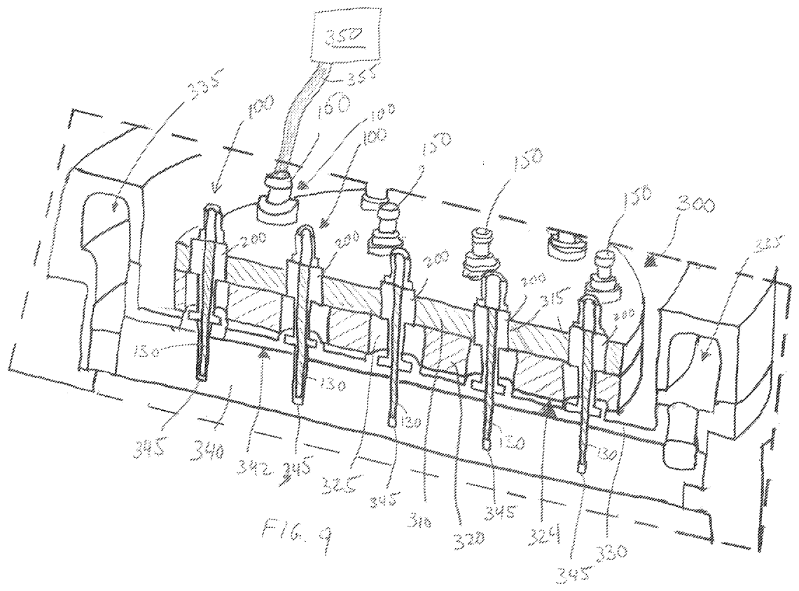

Referring to FIGS. 5 and 9, one or more embodiments of the disclosure are directed to plasma sources 300. The plasma sources 300 comprises an insulator plate 310 and a cooled plate 320. The cooled plate 320 includes a plurality of openings 325 extending therethrough and the insulator plate 310 as a plurality of openings 315 extending therethrough aligned with the plurality of openings 325 of the cooled plate 320. The plurality of openings 315 and the plurality of openings 325 are sized to allow an impedance transformer 100 to be positioned within the insulator plate 310 and extending through the cooled plate 320.

A pumping ring 330 is positioned below the cooled plate 320. The pumping ring 330 may include openings 335 to allow a flow of inert gases or process gases to pass through the pumping ring 330 to the exhaust system of the processing chamber.

A plurality of thermal breaks 100 as described herein are positioned within at least some of the plurality of openings 325 in the cooled plate 320, and at least some of the plurality of openings 315 in the insulator plate 310. The second end 214 of the housing 210 of the thermal breaks 200 extends below a bottom surface 324 of the cooled plate 320 and connected to the pumping ring 330.

A plasma plate 340 is positioned below the pumping ring 330. The plasma plate 340 comprises a plurality of pin openings 345 in a top surface 342 thereof. Each of the thermal breaks 200 comprises a microwave antennae pin 130 positioned within the channel 220 in the housing 210.

The microwave antennae pins 130 extend a distance L_{P} from the second end 214 of the housing 210 of the thermal breaks 200 into the pin openings 345 in the plasma plate 340. The microwave antennae pin 130 of some embodiments do not extend far enough from the second end 214 of the housing 210 to allow the second end 136 of the microwave antennae pin 130 to contact the bottom 346 of the pin openings 345.

In some embodiments, the overall length of the microwave antennae pin 130 from the first end 132 to the second end 136 is in the range of 60 mm to 200 mm, or in the range of 70 mm to 150 mm, or in the range of 80 mm to 125 mm, or in the range of 90 mm to 100 mm.

In some embodiments, the distance LP that the microwave antennae pin 130 extends below the second end 214 of the housing 210 of the thermal break 200 is in the range of 20 mm to 60 mm, or in the range of 25 mm to 50 mm, or in the range of 30 mm to 45 mm, or in the range of 35 mm to 40 mm.

In some embodiments, the microwave antennae pin 130 extends a depth D_{PS} into the plasma plate 340 by an amount in the range of 25 mm to 35 mm, or in the range of 26 mm to 34 mm, or in the range of 27 mm to 33 mm, or in the range of 28 mm to 32 mm, or in the range of 29 mm to 31 mm.

In some embodiments, the second end 136 of the microwave antennae pin 130 is spaced a distance from the bottom 346 of the pin openings 345 of the plasma plate 340 by an amount in the range of 0.25 mm to 5 mm, or in the range of 0.5 mm to 3 mm, or in the range of 0.75 mm to 2 mm, or in the range of 1 mm to 1.5 mm.

In some embodiments, the plasma source 300 comprises a microwave power source 350 that connects to one or more of, or each of, the microwave antennae pins 130 of the impedance transformer 100. The embodiment illustrated in FIG. 9 shows a single microwave power source 350 connected to a single coaxial connector 150 of a single impedance transformer 100 by a coaxial transmission line 355. In some embodiments, all of the impedance transformers 100 are connected to the same microwave power source 350 through separate coaxial transmission lines 355. In some embodiments, each of the impedance transformers 100 are connected to a separate microwave power source 350, or separate output of one or more microwave power source 350, through a coaxial transmission line 355, allowing the power provided to any individual impedance transformer 100 to be controlled.

In one or more embodiments, the channel 220 of the thermal breaks 200 have a curved taper with a plurality of linear facets 228 and the microwave antennae pin 130 has a substantially uniform diameter along a length of the microwave antennae pin 130. In some embodiments, the microwave antennae pin 130 extends a distance from the bottom of the thermal breaks 200 by a distance in the range of 27 mm to 34 mm and the microwave antennae pins have a diameter in the range of 3 mm to 4 mm.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. An impedance transformer comprising:
a thermal break comprising a housing having a first end and a second end defining a length of the housing, the housing having a channel with channel walls extending through the length from the first end to the second end, the channel having an opening in the first end of the housing with a first end diameter and an opening in the second end of the housing with a second end diameter, the first end diameter being greater than the second end diameter, the channel acting as a conical impedance transformer.

2. The impedance transformer of claim 1, wherein the channel walls have a curved taper.

3. The impedance transformer of claim 2, wherein the curved taper comprises a plurality of linear facets.

4. The impedance transformer of claim 3, wherein there are in the range of 2 to 15 facets.

5. The impedance transformer of claim 1, further comprising an upper sleeve positioned within the housing, the upper sleeve extending a distance into the housing from the first end.

6. The impedance transformer of claim 5, wherein the upper sleeve comprises polytetrafluoroethylene (PTFE).

7. The impedance transformer of claim 1, further comprising a lower sleeve positioned within the housing, the lower sleeve extending a distance into the housing from the second end.

8. The impedance transformer of claim 7, wherein the lower sleeve comprises polytetrafluoroethylene (PTFE).

9. The impedance transformer of claim 1, wherein at least a portion of the length of the housing comprises outwardly projecting and spaced apart vanes for heat dissipation.

10. The impedance transformer of claim 1, further comprising a microwave antennae pin positioned within the channel and extending a distance from the second end of the housing.

11. The impedance transformer of claim 10, wherein the microwave antennae pin comprises a beryllium copper pin.

12. The impedance transformer of claim 10, wherein the microwave antennae pin has a substantially uniform diameter along a length of the pin.

13. The impedance transformer of claim 12, wherein the diameter of the microwave antennae pin is in the range of 3 mm to 4 mm.

14. The impedance transformer of claim 1, wherein the housing comprises aluminum.

15. The impedance transformer of claim 1, further comprising a coaxial connector attached to the first end of the housing.

16. A plasma source comprising:
a cooled plate comprising a plurality of openings therethrough;
a pumping ring below the cooled plate;
a thermal break positioned within at least some of the plurality of openings, the thermal break comprising a housing having a first end and a second end defining a length of the housing, the housing having a channel with channel walls extending through the length from the first end to the second end, the channel having an opening in the first end of the housing with a first end diameter and an opening in the second end of the housing with a second end diameter, the first end diameter being greater than the second end diameter, the channel acting as a conical impedance transformer, the second end of the thermal breaks extending below a bottom surface of the cooled plate and connected to the pumping ring;
a plasma plate below the pumping ring, the plasma plate comprising a plurality of pin openings in a top surface thereof;
each of the thermal breaks comprising a microwave antennae pin positioned within the channel in the housing, the microwave antennae pins extending a distance from the second end of the housing of the thermal breaks into the pin openings in the plasma plate.

17. The plasma source of claim 16, wherein each of the microwave antennae pins are connected to a microwave power source.

18. The plasma source of claim 16, wherein microwave antennae pins comprise a beryllium copper pin.

19. The plasma source of claim 18, wherein the channel of the thermal breaks have a curved taper with a plurality of linear facets and the microwave antennae pin has a substantially uniform diameter along a length of the microwave antennae pin.

20. The plasma source of claim 19, wherein the microwave antennae pins extend a distance from the bottom of the thermal breaks by a distance in the range of 27 mm to 34 mm and the microwave antennae pins have a diameter in the range of 3 mm to 4 mm.
